(19) United States
(12) Patent Application Publication
(10) Pub. No.: US 2026/0076264 A1
(43) Pub. Date: Mar. 12, 2026

(54) MULTI-RETICLE DEVICE WITH ELECTRICAL AND OPTICAL STITCHING

(71) Applicant: Lightmatter, Inc., Boston, MA (US)

(72) Inventors: Mitul Modi, Phoenix, AZ (US); Anandaroop Ghosh, Hillsboro, OR (US); Tushar Dinkar Wakharkar, Cupertino, CA (US); Daniel Stodolsky, Cambridge, MA (US); Sandeep Sane, Chandler, AZ (US); Nikhil Kumar, East Palo Alto, CA (US)

(73) Assignee: Lightmatter, Inc., Boston, MA (US)

(21) Appl. No.: 19/323,149

(22) Filed: Sep. 9, 2025

Related U.S. Application Data
(60) Provisional application No. 63/693,140, filed on Sep. 10, 2024.

(51) Int. Cl. H01L 25/16; H01L 23/538

(52) U.S. Cl. CPC H10W 90/00; H10W 70/611; H10W 70/65

(57) ABSTRACT

Hybrid interconnect schemes that combine both electrical and optical stitching are described. Electrical stitching is well-suited for short-reach, high-bandwidth connections between adjacent or closely spaced units. On the other hand, optical stitching is well-suited for long-reach, low-loss connections between non-adjacent units. By leveraging the complementary nature of electrical and optical stitching, a multi-reticle device may be constructed that provides substantially greater scalability in terms of compute and memory density and overall interconnect bandwidth than is achievable using conventional approaches. An intermediate connection layer is configured to electrically connect electrical integrated circuits (EIC) of the plurality of EICs that are within a cutoff range of one another. An electro-optical interposer is configured to optically connect EICs of the plurality of EICs that are outside the cutoff range of one another.

### CROSS-REFERENCE TO RELATED APPLICATIONS

This Application claims the benefit under 35 U.S.C. § 119(e) of U.S. Provisional Application Ser. No. 63/693,140, filed on Sep. 10, 2024, under Attorney Docket No. L0858.70095US00, entitled “MULTI-RETICLE DEVICE ELECTRICAL AND OPTICAL STITCHING,” which is hereby incorporated herein by reference in its entirety.

### BACKGROUND

Computer systems include random-access memories (RAM) for storing data and machine code. RAMs are typically volatile memories, such that the stored information is lost when power is removed. In modern implementations, memories take the form of integrated circuits. Each integrated circuit includes several memory cells. To enable access to stored data and machine code, memories are placed in electrical communication with processors. Typically, these electrical communications are implemented as metal traces formed on the substrates on which the memories and the processors are disposed.

### SUMMARY OF THE DISCLOSURE

In some aspects, the techniques described herein relate to a multi-reticle device including: an intermediate connection layer including a top side and a bottom side; a plurality of electrical integrated circuits (EICs) coupled to the top side of the intermediate connection layer; and an electro-optical interposer coupled to the bottom side of the intermediate connection layer, the electro-optical interposer including a plurality of tiles, wherein each tile includes an electrical layer and an optical layer, wherein: the intermediate layer electrically connects a first EIC of the plurality of EICs to a second EIC of the plurality of EICs, wherein the first EIC is adjacent to the second EIC; and the electro-optical interposer optically connects the first EIC to a third EIC of the plurality of EICs, wherein the third EIC is not adjacent to the first EIC.

In some aspects, the techniques described herein relate to a multi-reticle device, wherein the intermediate connection layer includes a silicon bridge embedded in a mold matrix, wherein the silicon bridge electrically connects the first EIC to the second EIC.

In some aspects, the techniques described herein relate to a multi-reticle device, wherein the intermediate connection layer further includes a plurality of vertical connections embedded in the mold matrix, plurality of vertical connections electrically connecting the first EIC to the electro-optical interposer.

In some aspects, the techniques described herein relate to a multi-reticle device, wherein the intermediate connection layer includes a silicon interposer.

In some aspects, the techniques described herein relate to a multi-reticle device, wherein the intermediate connection layer includes a redistribution layer.

In some aspects, the techniques described herein relate to a multi-reticle device, further including a redistribution layer coupled to the electro-optical interposer such that the electro-optical interposer is between the intermediate connection layer and the redistribution layer.

In some aspects, the techniques described herein relate to a multi-reticle device, wherein the plurality of EICs include a plurality of memory chips and at least one application specific integrated circuit (ASIC).

In some aspects, the techniques described herein relate to a multi-reticle device, wherein the plurality of EICs are arranged in a plurality of unit cells, each unit cell including at least one ASIC and at least four memory chips.

In some aspects, the techniques described herein relate to a multi-reticle device including: a plurality of electrical integrated circuits (EICs) arranged in a plurality of unit cells, each unit cell including at least one application specific integrated circuit (ASIC) and a plurality of memory chips; an intermediate connection layer including a top side and a bottom side, wherein the plurality of EICs are coupled to the top side of the intermediate connection layer, wherein the intermediate connection layer is configured to electrically connect an ASIC of a first unit cell of the plurality of units cells to the plurality of memory chips of the first unit cell; and an electro-optical interposer including a plurality of tiles, wherein the electro-optical interposer is coupled to the bottom side of the intermediate connection layer, wherein the electro-optical interposer is configured to optically connect the ASIC of the first unit cell to the plurality of memory chips of a second unit cell of the plurality of unit cells.

In some aspects, the techniques described herein relate to a multi-reticle device, further including a plurality of vertical connections formed in the intermediate connection layer, the plurality of vertical connections electrically connecting tiles of the electro-optical interposer to unit cells in accordance with a 1-to-1 correspondence.

In some aspects, the techniques described herein relate to a multi-reticle device, further including a plurality of vertical connections formed in the intermediate connection layer, the plurality of vertical connections electrically connecting tiles of the electro-optical interposer to unit cells in accordance with a N-to-1 correspondence, where N is greater than 1.

In some aspects, the techniques described herein relate to a multi-reticle device, wherein the intermediate connection layer includes at least one selected from the group consisting of a redistribution layer, a silicon interposer and a plurality of silicon bridges.

In some aspects, the techniques described herein relate to a multi-reticle device, further including a Universal Chiplet Interconnect Express (UCIe) interface configured to place the ASIC of the first unit cell in communication with the plurality of memory chips of the first unit cells.

In some aspects, the techniques described herein relate to a multi-reticle device, further including a redistribution layer coupled to the electro-optical interposer such that the electro-optical interposer is between the intermediate connection layer and the redistribution layer.

In some aspects, the techniques described herein relate to a multi-reticle device including: an intermediate connection layer including a top side configured to be electrically coupled to a plurality of electrical integrated circuits (EIC), wherein the intermediate connection layer is configured to electrically connect EICs of the plurality of EICs that are within a cutoff range of one another; and an electro-optical interposer co-packaged with the intermediate connection layer, wherein the electro-optical interposer is configured to optically connect EICs of the plurality of EICs that are outside the cutoff range of one another.

In some aspects, the techniques described herein relate to a multi-reticle device, wherein the cutoff range is 5 mm.

In some aspects, the techniques described herein relate to a multi-reticle device, wherein the cutoff range is 3 mm.

In some aspects, the techniques described herein relate to a multi-reticle device, wherein the intermediate connection layer includes at least one selected from the group consisting of a redistribution layer, a silicon interposer and a plurality of silicon bridges.

In some aspects, the techniques described herein relate to a multi-reticle device, further including a Universal Chiplet Interconnect Express (UCIe) interface configured to place connect EICs that are within the cutoff range of one another in communication with one another.

In some aspects, the techniques described herein relate to a multi-reticle device, further including a redistribution layer coupled to the electro-optical interposer such that the electro-optical interposer is between the intermediate connection layer and the redistribution layer.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a cross sectional side view of a multi-reticle device including silicon bridges, in accordance with some embodiments.

FIG. 1B is a cross sectional side view of a multi-reticle device including a silicon interposer, in accordance with some embodiments.

FIG. 1C is a cross sectional side view of a multi-reticle device including two redistribution layers, in accordance with some embodiments.

FIG. 1D is a cross sectional side view of another multi-reticle device including two redistribution layers, in accordance with some embodiments.

FIG. 2A is a top view of the multi-reticle device of FIG. 1B, in accordance with some embodiments.

FIG. 2B is a top view of an electro-optical tile that may be used as part of the multi-reticle device of FIG. 2A, in accordance with some embodiments.

FIG. 3 is a cross sectional side view of a multi-reticle device including an out-of-plane coupler, in accordance with some embodiments.

FIG. 4A illustrates a semiconductor wafer, in accordance with some embodiments.

FIG. 4B illustrates a set of photomasks, in accordance with some embodiments.

FIG. 4C illustrates an example photomask for forming optical waveguides, in accordance with some embodiments.

FIG. 4D illustrates the wafer of FIG. 4A patterned in accordance with the photomask set of FIG. 4B, in accordance with some embodiments.

FIG. 4E illustrates the patterned wafer of FIG. 4D marked with six photonic circuits, in accordance with some embodiments.

FIG. 5A illustrates electrical components of a reticle-stitched electro-optical interposer, in accordance with some embodiments.

FIG. 5B illustrates optical components of a reticle-stitched electro-optical interposer, in accordance with some embodiments.

### DETAILED DESCRIPTION

Artificial intelligence (AI) training workloads typically require extremely high bandwidth connectivity between memory chips and xPUs (e.g., central processing units (CPU), graphical processing units (GPU), tensor processing units (TPU), and other specialized processors). Conventional approaches to integrating memory and xPUs on a single electrically connected wafer-scale matrix, together with high-bandwidth interconnects between memory and xPU complexes, have been constrained by the limitations of high volume manufacturing. In particular, the scalability of silicon reticle stitching and package-to-package communication imposes restrictions on the number of compute units and shared memory resources that may be implemented on a single tray, as well as on the inter-tray bandwidth that can be achieved.

The inventors have recognized and appreciated that achieving a complex with maximized memory capacity cannot be accomplished through electrical interconnects alone, due to inherent bandwidth, power, distance and scalability limitations. Instead, it would be advantageous to employ a hybrid interconnect scheme that combines both electrical and optical stitching. Electrical stitching is well-suited for short-reach, high-bandwidth connections between adjacent or closely spaced units. On the other hand, optical stitching is well-suited for long-reach, low-loss connections between non-adjacent units. By leveraging the complementary nature of electrical and optical stitching, a multi-reticle device may be constructed that provides substantially greater scalability in terms of compute and memory density and overall interconnect bandwidth than is achievable using conventional approaches.

Devices of the types described herein are said to be multi-reticle in that they are fabricated using reticle-stitching manufacturing techniques, examples of which are described in detail further below. Reticle stitching is a photolithographic technique that enables seamless integration of multiple reticles on a semiconductor wafer to create a larger, continuous circuit. Using this approach, adjacent tiles are precisely aligned and patterned such that features extend across their shared boundaries. This allows for both optical and electrical interconnects between neighboring tiles, effectively forming a continuous circuit architecture extending beyond the size limitations of a single reticle exposure.

Accordingly, both electrical and optical stitching are employed in some embodiments to interconnect tiles within a multi-reticle device. Stitched electrical and optical circuits may be embedded as part of a common substrate, referred to herein as electro-optical interposer. Adjacent chips (also referred to as electrical integrated circuits (EIC)) may be interconnected using electrical interconnects such as conductive traces. In contrast, chips that are not adjacent to one another may be interconnected using optical links, such as on-chip optical waveguides. Some embodiments further include an intermediate connection layer disposed between the EICs and the electro-optical interposer. The intermediate connection layer may be implemented as a redistribution layer (RDL), silicon interposer or multiple silicon bridges embedded in a mold matrix.

In some embodiments, optimal use of the compute tile area may be achieved by forming an underlying electro-optical tile that is a fraction (e.g., one half, one third, one quarter, etc.) of the compute unit cell. This configuration enables the aggregate unit cell—comprising compute nodes, memory chips and electro-optical interconnects—to exceed the size of a single electro-optical reticle.

Although several embodiments are described with reference to memory chips and application specific integrated circuits (ASIC), the present disclosure is not limited to such devices. Any EIC may be employed.

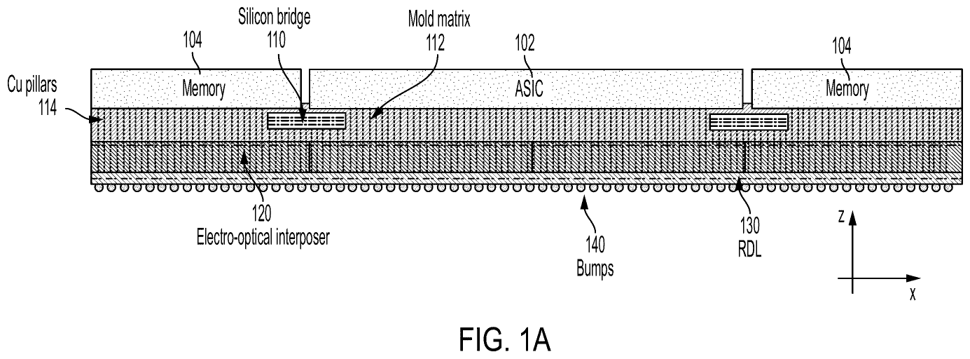

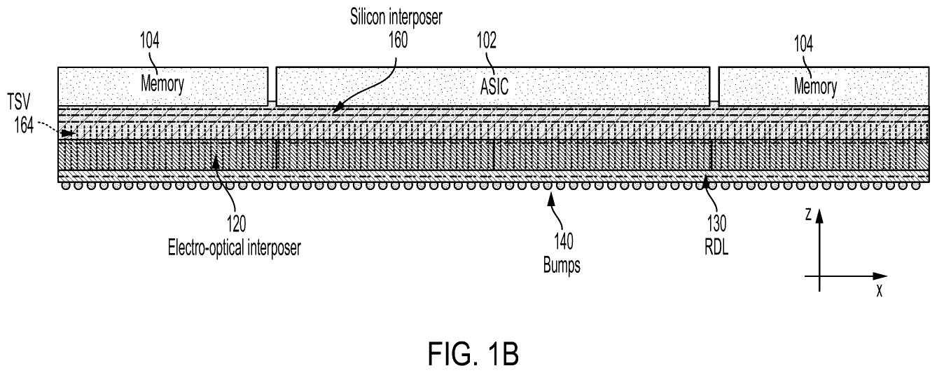

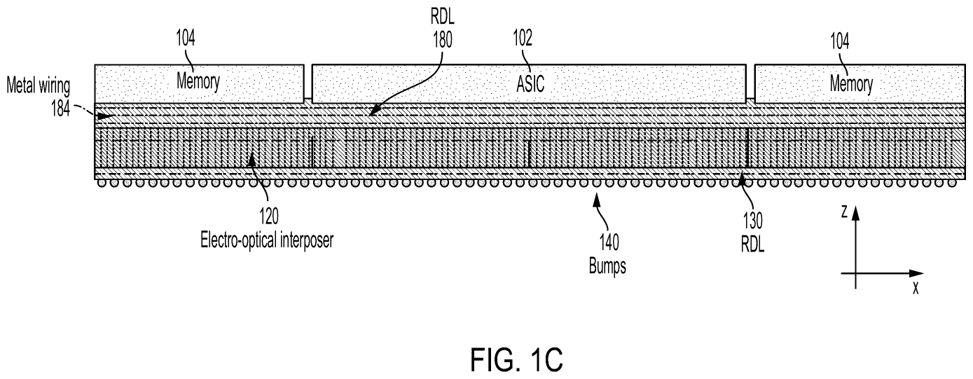

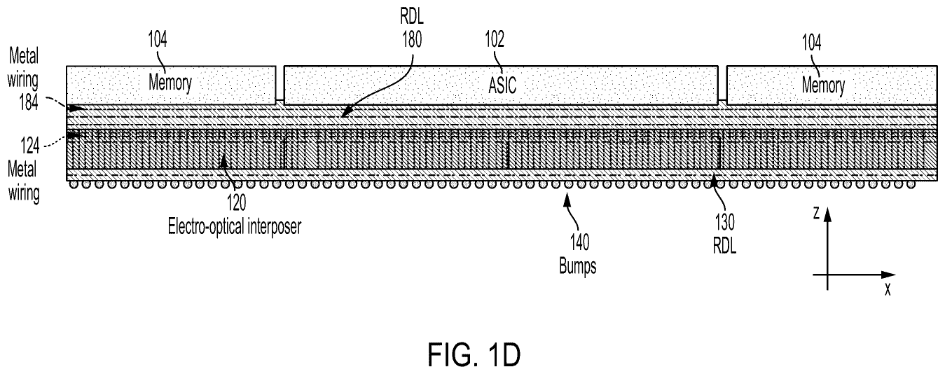

FIGS. 1A-1D are cross sectional side views of alternative multi-reticle devices, in accordance with some embodiments. These devices differ from one another in the type of intermediate connection layer used to provide electrical interconnectivity. In the device of FIG. 1A, electrical interconnections are supported by silicon bridges; in the device of FIG. 1B, electrical interconnections are supported by a silicon interposer; in the devices of FIGS. 1C-1D, electrical interconnections are supported by a redistribution layer (RDL).

In some embodiments, the intermediate connection layer is hybrid bonded to the electrical-optical interposer. Hybrid bonding is a manufacturing technique used to join two semiconductor substrates that is based in part on chemical bonding and in part on mechanical interlocking at the molecular level. Prior to bonding, the surfaces of the substrates are polished to achieve extreme flatness, for example using chemical-mechanical polishing (CMP), to ensure intimate contact between the surfaces without gaps. The surfaces of the two substrates are subsequently brought into direct contact at the molecular level, eliminating the need for an intermediate adhesive or solder material. As such, conductive pads formed on the surface of one substrate come in direct electrical contact with conductive pads formed on the surface of the other substrate, without having to resort to solder bumps or other types of connections between the substrates.

Referring first to FIG. 1A, the intermediate connection layer is implemented using silicon bridges embedded in a mold matrix. The intermediate connection layer is co-packaged with an electro-optical interposer. The multi-reticle depicted in this figure includes multiple electrical integrated circuits (EIC) coupled to a stack including a mold matrix 112, an electrical optical interposer 120 and a redistribution layer (RDL) 130. The EICs are mounted to mold matrix 112. Mold matrix 112 incudes copper pillars 114, which are electrically coupled to the EICs. Electrical-optical interposer 120 is disposed between mold matrix 112 and RDL 130. Bumps 140 connect RDL 130 to an underlying carrier, substrate or circuit board. In this example, the EICs include a pair of memory chips 104 and an application specific integrated circuit (ASIC) 102. Examples of ASICs include xPUs, microcontrollers, field programmable gate arrays (FPGAs), etc. Examples of memories include high-bandwidth memories (HBM), NAND memories, dynamic random access memories (DRAM), Flash memories, etc. Silicon bridges 110 are embedded inside the mold matrix 112. The silicon bridges permit electrical communication between ASIC 102 and each memory chip 104. The silicon bridges may be implemented in accordance with an Embedded Multi-die Interconnect Bridge (EMIB) standard (e.g., EMIB-T) or CoWoS-L, among other possible protocols.

ASIC 102 and memory chips 104 are mounted to the top side of mold matrix 112; electro-optical interposer 120 is coupled to the bottom side of mold matrix 112. Copper pillars 114 (or other types of vertical connections such as through-mold vias) traverse the mold matrix in the vertical direction (z-axis), electrically connecting the EICs to electro-optical interposer 120. In some embodiments, silicon bridges 110 themselves may include through-mold vias connecting the EICs to electro-optical interposer 120.

Electro-optical interposer 120 includes programmable optical networks configured to allow optical communication between different components of the device and/or to other devices. The optical networks are programmable in that they include optical switches that can couple different components to one another, in one direction or the other, depending on the needs of the computing system. Electro-optical interposer 120 further includes optical waveguides that support propagation of optical modes, modulators that convert electrical signals into optical signals, detectors that convert optical signals into electrical signals and optical couplers that permit connection to external fibers. As described in detail further below, electro-optical interposer 120 includes multiple tiles formed using reticle stitching techniques. This allows electro-optical interposer 120 to extend well beyond what is possible using single reticle shot implementations.

RDL 130 is a thin layer of metal wirings configured to reroute input/output (I/O) connections between electro-optical interposer 120 and the underlying carrier, substrate or circuit board. RDL 130 allows signals and power to be redistributed from the bond pad provided on the bottom surface of electro-optical interposer 120 to a new set of locations that better match the requirements of the package. This provides flexibility of connecting the stack of FIG. 1A to the underlying carrier, substrate or circuit board.

The multi-reticle device of FIG. 1B is similar to the device of FIG. 1A in that it includes EICs coupled to a stack including a electro-optical interposer and an RDL. In the device of FIG. 1B, however, the intermediate connection layer is implemented using a silicon interposer 160. Silicon interposer 160 includes a thin layer of silicon provided as an intermediate substrate to connect multiple EICs with each other. It provides a high-density wiring platform that enables fine-pitch interconnection between the EICs. Silicon interposer 160 can be passive or active. A passive interposer 160 includes only wiring and vias (e.g., through-silicon vias (TSV)). An active interposer 160, on the other hand, further includes active circuitry, such as power management, signal conditioning and logic blocks, allowing the interposer not only to route signals, but also to offload certain functions from the other components of the device.

The multi-reticle device of FIG. 1C is also similar to the device of FIG. 1A in that it includes EICs coupled to a stack including electro-optical interposer and RDL. In the device of FIG. 1C, however, the intermediate connection layer is implemented using an RDL 180. Therefore, in this implementation, electro-optical interposer 120 is sandwiched between two RDLs. RDL 180 is a thin layer of metal wirings 184 configured to reroute I/O connections between the EICs and electro-optical interposer 120.

The multi-reticle device of FIG. 1D is similar to the device of FIG. 1C in that it also includes RDL 180 playing the role of the intermediate connection layer. The main distinction, however, is that additional metal wirings 124 (formed near the top side of electro-optical interposer 120) can support communication between the EICs in the electrical domain. As such, electrical communication between EICs can be supported by metal wiring 124 as well as by metal wiring 184.

The multi-reticle devices of FIGS. 1A-1D are illustrated with electro-optical interposer 120 extending across the entire surface of the multi-reticle device. In other embodiments, however, an electro-optical interposer 120 may extend only through a portion of the surface of the multi-reticle device. For example, electro-optical interposer 120 may not extend to the regions near the edges and/or the corners of the multi-reticle device.

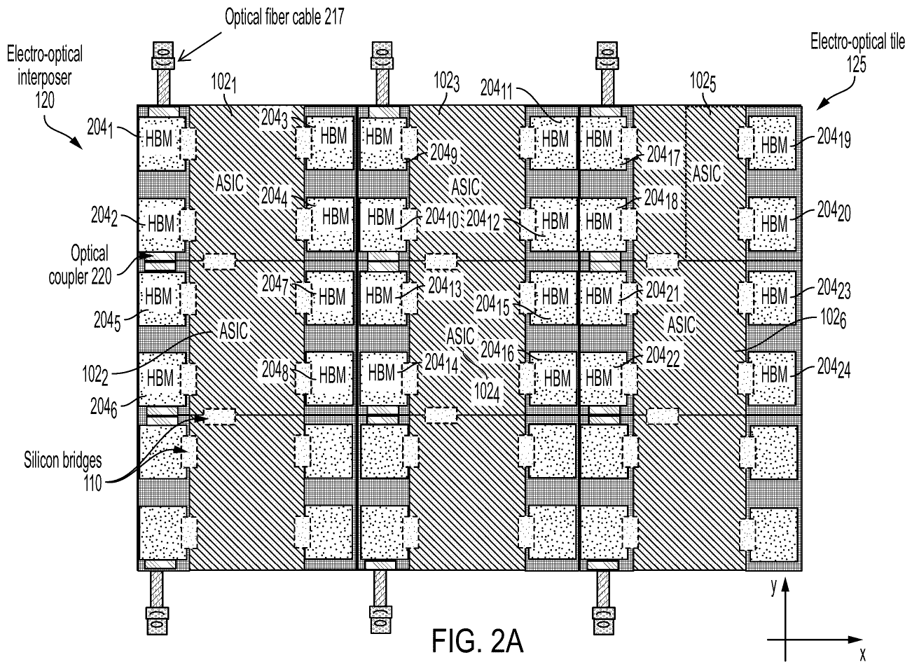

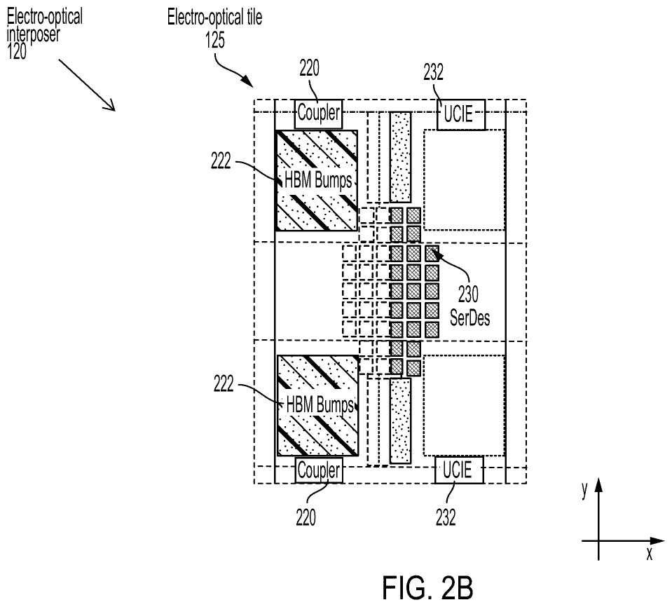

FIG. 2A is a top view of the multi-reticle device of FIG. 1B, in accordance with some embodiments. The multi-reticle devices of FIG. 1A and FIGS. 1C-1D may have similar top views. In this example, the device includes nine unit cells organized in a 3×3 configuration, where each unit cell includes one ASIC and four high-bandwidth memories (HBM) (in this example, the memories of FIG. 1B are implemented as HBMs, but other types of memories are also possible). A unit cell is a layout of EICs that is repeated in multiple instances across the device. It should be noted that a unit cell may include more than one ASIC and/or more than four HBMs per ASIC in some embodiments. Further, arrangements other than the 3×3 configuration of FIG. 2A are also possible.

FIG. 2A illustrates that communication between EICs is carried out either in the electrical domain or in the optical domain depending on the relative location of the EICs in the device. Electrical-domain communication between EICs is supported using an intermediate connection layer: silicon bridges 110 in the example of FIG. 2A, or alternatively, silicon interposer 160 or RDL 180. Optical-domain communication between EICs is supported using electro-optical interposer 120 (in FIG. 2A, electro-optical interposer 120 is not shown because it is hidden by the components disposed on top of it, including the HBMs, the ASICs and the intermediate connection layer). As discussed in detail further below, electro-optical interposer 120 may be organized in tiles (referred to as electro-optical tiles 125).

The device may rely on electrical communication for relatively short data paths, but may rely on optical communication for longer data paths, where limitations imposed by the inherent impedance associated with the conductive wirings is expected to negatively affect performance too significantly. In one example, communication between adjacent EICs is carried out in the electrical domain and communication between non-adjacent EICs is carried out in the optical domain. EICs are said to be adjacent to each other if they share a common boundary or are positioned directly beside each other. If there is one chip located between a pair, either along the x-axis or the y-axis, the chips of that pair are not adjacent to each other. In the example of FIG. 2A, ASIC 102₁ is adjacent to HBMs 204₁, 204₂, 204₃ and 204₄ as well as to ASIC 102₂. By contrast, ASIC 102₁ is not adjacent to HBMs 204₅, 204₆, 204₇, 204₈, 204₉, 204₁₀, 204₁₁, 204₁₂, 204₁₃, 204₁₄, 204₁₅, 204₁₆, 204₁₇, 204₁₈, 204₁₉, 204₂₀, 204₂₁, 204₂₂, 204₂₃ or 204₂₄, or to ASICs 102₃, 102₄, 102₅ and 102₆. Similarly, HBM 104₁₀ is adjacent to HBMs 204₃, 204₉, 204₄, 204₇, and 204₁₃ as well as to ASIC 102₃, but is not adjacent to HBMs 204₁, 204₂, 2045, 204₆, 204₈, 204₁₄ and 204₁₁₋₂₄ or to ASICs 102₁, 102₂, 102₄, 102₅ and 102₆. It should be noted that not all the EICs of FIG. 2A are labelled. In another example, communication between EICs is carried out in the electrical domain if the EICs are within a cutoff range of each other and is carried out in the optical domain if the EICs are outside the cutoff range. The cutoff may be 1 mm, 2 mm, 3 mm, 4 mm, 5 mm, 6 mm, 7 mm, 8 mm, 9 mm or 10 mm, for example. In yet another example, an ASIC communicates with memory chips that belong to the same unit cell as the ASIC in the electrical domain and communicates with memory chips that are outside the ASIC's unit cell in the optical domain.

As further shown in FIG. 2A, optical fiber cables 217 place the device in communication with other devices. Optical couplers 220 permit optical communication between tiles of electro-optical interposer 120. Additional optical couplers 220 are connected to fiber cables.

Electro-optical interposer 120 is organized in electro-optical tiles in that it is fabricated in accordance with reticle-stitching manufacturing techniques. Reticle stitching enables seamless integration of multiple tiles on a semiconductor wafer to create a larger, continuous electro-optical optical circuit. Each tile represents the photolithographic instantiation of a template layout—the reticle. In the example of FIG. 2A, each electro-optical tile 125 is half the size of a unit cell. As such, each electro-optical tile 125 overlaps with a pair of HBMs and half an ASIC. In this arrangement, the tiles and the unit cells are said to be connected in accordance with a 2-to-1 correspondence. More generally, implementations based on an N-to-1 correspondence are also possible, where N is greater than 1. In the example of FIG. 2A, two electro-optical tiles 125 are used for each unit cell, leading to eighteen electro-optical tiles 125 in total across the device. In other implementations, each electro-optical tile 125 is half the size of a unit cell, leading to a 1-to-1 correspondence.

FIG. 2B is a top view of the electro-optical tile 125 which is used as part of the multi-reticle device of FIG. 2A. It should be noted that the depiction of FIG. 2A is limited to some of the electrical layers that constitute the tile; notably, the optical layers are not shown in FIG. 2B. As shown, the tile includes two areas designated for connection to respective HBMs (HBM bumps 222). HBM bumps 222 may include conductive pads on which bumps connected to the intermediate connection layer land. The tile further includes serializers-deserializers (SerDes) 230, which are configured to interface with the underlying optical network by providing data serialization and deserialization. The serializers may be connected to optical transmitters, including modulator drivers and modulators. The deserializers may be connected to optical receivers, including detectors and transimpedance amplifiers (TIA). The modulator drivers and the TIAs may be formed as part of the electrical layers of electro-optical tile 125. As described in connection with FIG. 2A, optical couplers 220 place adjacent tiles in optical communication with each other. Additional optical couplers 220 connect interposer 120 to external optical fibers.

The size of electro-optical tile 125 may correspond to the reticle size governed by the stepper equipment of the semiconductor foundry. For example, the area of a tile may be between 500 mm² and 1500 mm², between 750 mm² and 1500 mm², between 1000 mm² and 1500 mm², between 1250 mm² and 1500 mm², between 500 mm² and 1250 mm², between 750 mm² and 1250 mm², between 1000 mm² and 1250 mm², between 500 mm² and 1000 mm², between 750 mm² and 1000 mm², between 800 mm² and 900 mm², although other ranges are also possible. In one example, the area of a tile is 26 mm×33 mm.

In some embodiments, electrical communication between EICs through silicon bridges 110 is supported by the Universal Chiplet Interconnect Express (UCIe) standard (including for example UCIe-AP or UCIe-SP), an open industry standard designed to enable seamless communication between chips within a single package. As such, the tile includes an UCIe interface 232. Alternatively, electrical communication between EICs may be supported by other standards, including for example die-to-die Advanced Interface Bus (AIB), Ethernet, Peripheral Component Interconnect Express (PCIe), Bunch of Wires (BoW), NVLINK, etc.

The electro-optical tile 125 of FIG. 2B is designed so that a pair of HBMs are aligned near the boundary on the left-hand side of the tile. However, other arrangements are also possible. In another embodiments, HBMs may be aligned in pair near the boundary on the right-hand side of the tile, near the boundary on the top side of the tile or near the boundary on the bottom side of the tile.

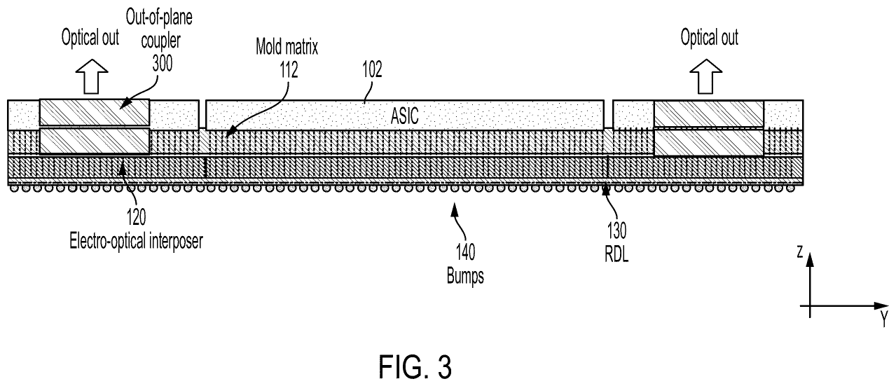

The inventors have further developed out-of-plane couplers that enable fiber coupling to any location within a multi-reticle device. FIG. 3 is a cross sectional side view of a multi-reticle device including out-of-plane couplers 300, in accordance with some embodiments. Out-of-plane couplers 300 are embedded in the device and extend through the intermediate connection layer (implemented as a mold matrix 112 in this example, but other types of intermediate connection layers are also compatible with out-of-plane couplers 300). An out-of-plane coupler may include an optical component that steers light received from a waveguide outside the plane of the waveguide. That component may include for example a grating and/or a mirror. An out-of-plane coupler may further include a structure embedded in the intermediate connection layer that confines light to propagate in the vertical direction. Light is emitted outside the plane of the device in the vertical direction, and is collected using a fiber and/or a system of mirrors. Unlike edge couplers, which are positioned near an edge of a device, out-of-plane coupler 300 can be placed anywhere within a multi-reticle device, thus enhancing fiber connectivity.

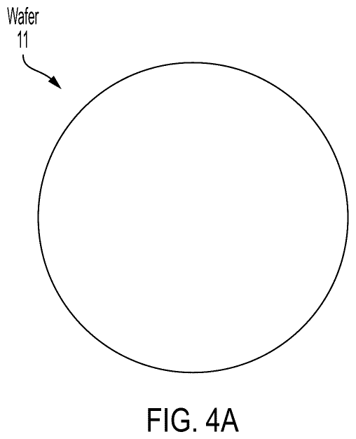

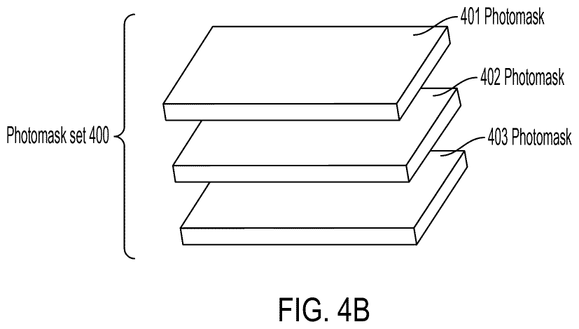

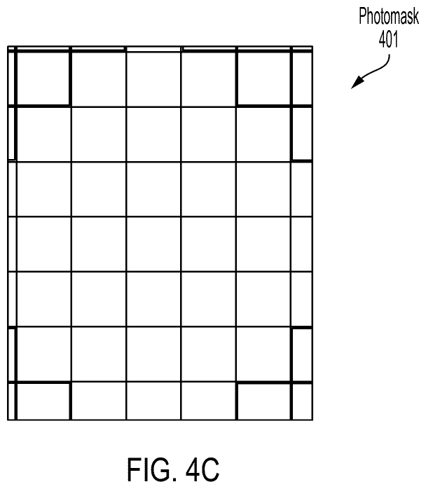

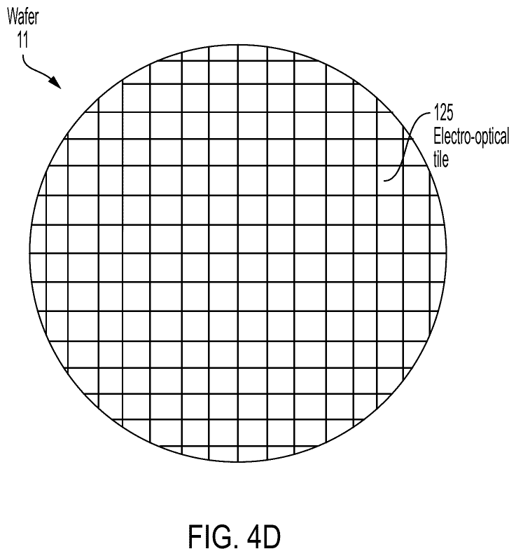

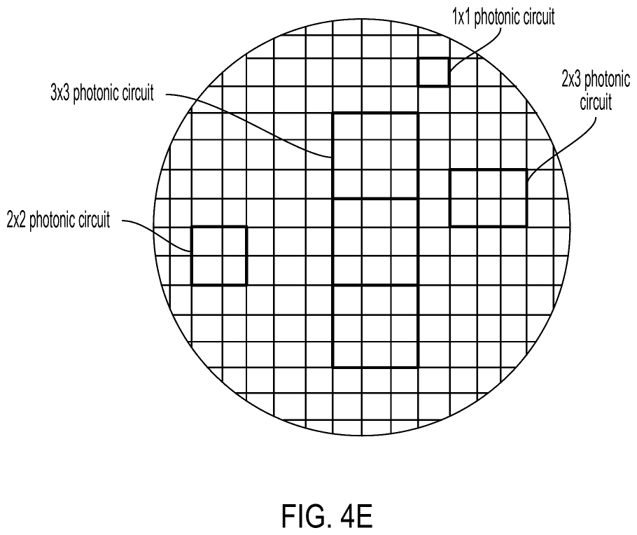

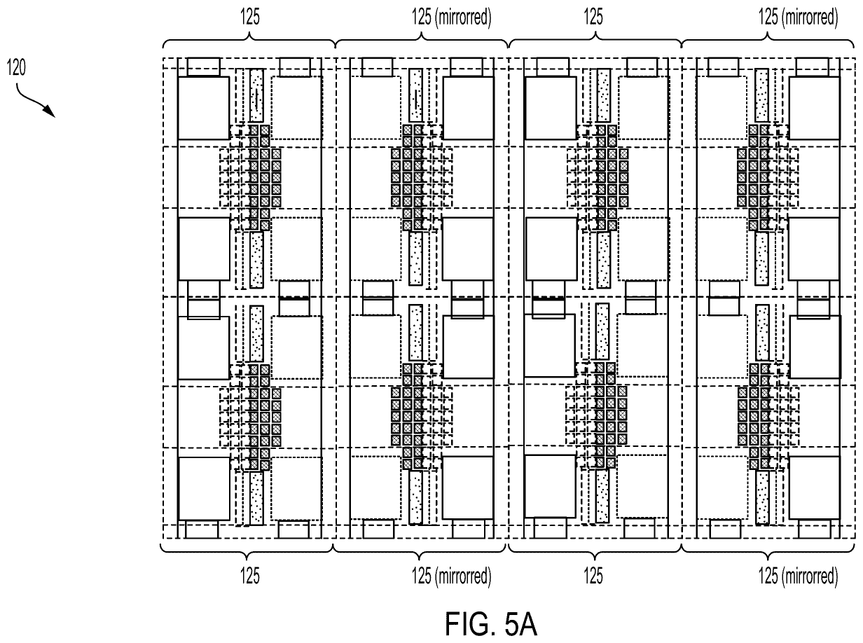

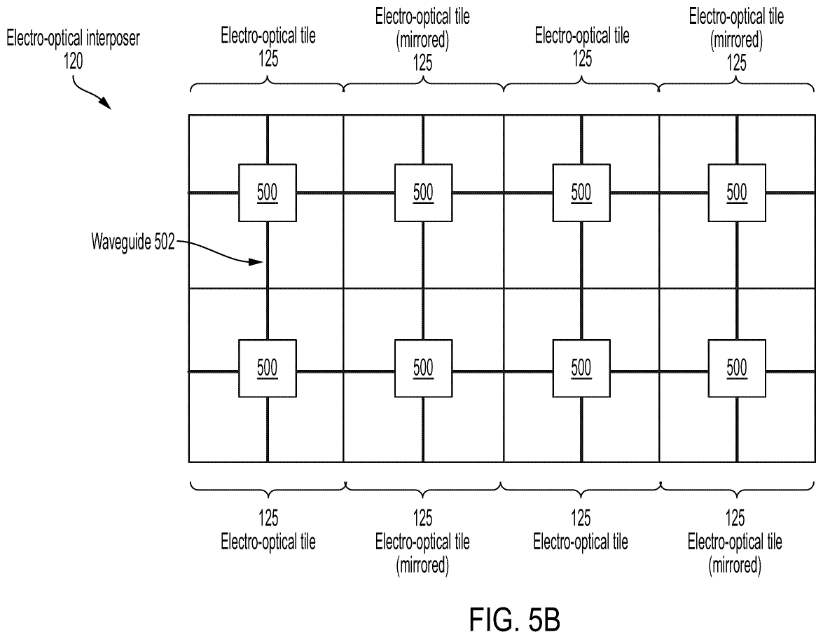

The tiles described herein may be manufactured using microfabrication techniques, including for example complementary metal-oxide-semiconductor (CMOS) microfabrication techniques. Accordingly, some embodiments relate to silicon photonics-based electro-optical interposers. Some particular microfabrication techniques involve step-and-repeat approaches—whereby stepper machines are used to pattern a semiconductor wafer with multiple copies of a template layout (e.g., a reticle). Each tile that results from the step-and-repeat approach may correspond to a reticle. Reticle stitching is a photolithographic technique that enables seamless integration of multiple reticles on a semiconductor wafer to create a larger, continuous circuit. Using this approach, adjacent tiles are precisely aligned and patterned such that features extend across their shared boundaries. This allows for both optical and electrical interconnections between neighboring tiles, effectively forming a continuous circuit architecture extending beyond the size limitations of a single reticle exposure. FIG. 4A through FIG. 4E illustrate microfabrication techniques for manufacturing tiles. FIGS. 5A and 5B illustrate examples of tiles patterned using these microfabrication techniques.

Referring first to FIG. 4A, this figure illustrates a semiconductor wafer 11. Wafer 11 may be made of any material. For example, wafer 11 may be made of (or otherwise include) silicon. In one example, wafer 11 is a silicon-on-insulator (SOI) wafer. In another example, wafer 11 is a bulk silicon wafer. Wafer 11 may have any size. For example, the diameter of wafer 11 may be 150 mm, 300 nm, or 450 mm, among other possible values. However, not all wafers need to have a circular shape.

FIG. 4B illustrates a set of photomasks that may be used for patterning wafer 11 using photolithographic techniques. Photomask set 400 includes three illustrative photomasks (401, 402 and 403), though the set may include additional photomasks. Each photomask has a particular pattern of opaque and transparent regions. When the photomask is exposed to light, the opaque regions block the light, thereby preventing it from shining a wafer, and the transparent regions allow passage of the light. The result is that the pattern of the photomask is transferred to the wafer.

Each photomask may define a particular layer of a tile. One photomask may be used to define optical waveguides. When the wafer goes through an etch process, only the exposed regions (or only the non-exposed regions) are etched away, while the other regions remain un-etched. This photomask may be patterned to form a network of optical waveguides when the wafer is exposed to light through this photomask. FIG. 4C illustrates a portion of a photomask that may be used to form waveguides on wafer 11. The lines of photomask 401 represent opaque regions. The background of photomask 401 is transparent. Exposure of photomask 401 to light so that an image of the photomask is projected onto wafer 11 enables patterning of waveguides in the shapes of the opaque regions. In this particular example, the pattern of lines of the photomask results in a grid of waveguides.

Some tiles involve use of different levels of optical waveguides. In some such embodiments, photomask set 400 may include a dedicated photomask for each waveguide level. Another photomask may be used to define n-doped regions. When the wafer goes through an ion implantation or dopant diffusion process, only the exposed regions (or only the non-exposed regions) receive the doping, while the other regions remain undoped. Another photomask may be used to define p-doped regions using a similar process. Some tiles involve use of different doping concentrations. In some such embodiments, photomask set 400 may include a dedicated photomask for each doping concentration. In other embodiments, photomask set 400 may include photomasks used to define deposition of semiconductor materials other than silicon, such as germanium and/or other materials of the periodic table, such as Groups III or V. Another photomask may be used to define metal contacts. Another photomask may be used to define metal traces. Some tiles involve use of different levels of metal traces. In some such embodiments, photomask set 400 may include a dedicated photomask for each metal trace level.

In some embodiments, wafer 11 is patterned in a step-and-repeat fashion. When wafer 11 is processed in a stepper machine, the pattern of a photomask is exposed repeatedly across the surface of the wafer, in a grid. This process involves moving the wafer in steps back and forth and left and right under the lens of the stepper, and exposing the photomask at each step. The result is that wafer 11 is patterned with multiple copies of the pattern defined by a photomask. This operation may be repeated for each photomask (or at least some photomasks) of the set. Thus, in some embodiments, the tiles are copies of a common template tile that are stitched together in a 1D or a 2D arrangement. Other embodiments involve two template tiles, so that each tile of an interposer is formed either as an instantiation of the first template tile or an instantiation of the second template tile. Tiles of different templates may alternate in a checkerboard-like fashion, for example, such that each tile of the first type only neighbors with tiles of the second type. Other arrangements are also possible.

In the example of FIG. 4D, wafer 11 has been patterned with a grid of electro-optical tiles 125. The tiles may share the pattern of one or more photomasks of set 400. For example, the tiles may share the pattern of the same waveguide photomask(s) and/or the same m trace photomask(s). In other embodiments, the tiles share the pattern of all the photomasks of set 400. For example, the tiles may share the same optical waveguide pattern, the same n-doping pattern, the same p-doping pattern, the same contact pattern, the same metal trace pattern, the same electrical circuitry pattern, the same conductive pad pattern, the same via pattern, etc.

In some embodiments, the entire surface of wafer 11 is patterned using photomask set 200. However, not all embodiments are limited in this respect as some portions of wafer 11 may be patterned using a first photomask set and other portions of wafer 11 may be patterned using a second photomask set. The first photomask set may correspond to a first reticle and the second photomask set may correspond to a second reticle. The first and second types of reticles may alternate in a checkerboard-like fashion.

Once patterned, wafer 11 may include multiple photonic circuits. In one example, the wafer of FIG. 4E has been marked to obtain six photonic circuits from wafer 11. The photonic circuits are monolithically integrated within the wafer. This figure identifies a 1×1photonic circuit having only one tile, a 2×2 photonic circuit having four tiles, a 2×3 photonic circuit having six tiles, and three 3×3 photonic circuits having nine tiles each. Separation of a photonic circuit from the wafer involves dicing the wafer along the perimeter of the desired photonic circuit. In this respect, the photonic circuits described herein may be viewed as a wafer-level architecture. Once diced, each photonic circuit forms a standalone electrical-optical interposer. One of the 3×3 photonic circuits of wafer 11 may be used to implement the electro-optical interposer of FIG. 2A.

FIG. 5A illustrates electrical components of an example of a reticle-stitched electro-optical interposer (the electrical layer), and FIG. 5B illustrates optical components of the reticle-stitched electro-optical interposer (the optical layer), in accordance with some embodiments. The electro-optical interposer is formed by reticle-stitching multiple reticles in the manner described in connection with FIGS. 4A-4E. In this example, the electro-optical interposer is obtained by dicing a 4×2 photonic circuit off of wafer 11. Other interposers, however, may span across more tiles (e.g., more than four rows and/or more than two columns). In some embodiments, an interposer may span the entire surface of a wafer 11, or at least 40% of the surface of a wafer, or at least 50% of the surface of a wafer, or at least 60% of the surface of a wafer, or at least 70% of the surface of a wafer, or at least 80% of the surface of a wafer, or at least 90% of the surface of a wafer.

The electrical layers of the electro-optical interposer of FIG. 5A are patterned in accordance with the tile shown in FIG. 2B. This interposer includes eight tiles arranged in a checkerboard pattern. Half of the tiles are patterned using the tile as shown in FIG. 2B; the other half is patterned by mirroring the tile shown in FIG. 2B. The mirroring plane is defined by the eastern boundary of the tile of FIG. 2B, parallel to the y-axis.

Referring now to FIG. 5B, stitching the tiles together further creates a continuous photonic circuitry spanning across all the tiles. As such, any tile can optically communicate with any other tile. The photonic circuitry includes waveguides 502 and optical switches 500. Waveguides 502 are configured to permit passage of optical signals from one tile to an adjacent tile, across the boundary defined between them. For example, a coupler 220 may be formed by physically connecting the waveguides of two adjacent tiles; alternatively, a coupler 220 may be formed by positioning waveguides to evanescently couple to each other across the tile boundary. Optical switches 500 enables the photonic network to be programmable—any tile can be paired with any other tile in one direction of communication or the other. Optical switches 500 may be implemented for example using resonant devices (e.g., microring resonators) or Mach-Zehnder interferometers.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within +2% of a target value in some embodiments. The terms “approximately”and “about” may include the target value.

What is claimed is:

1. A multi-reticle device comprising:
an intermediate connection layer comprising a top side and a bottom side;
a plurality of electrical integrated circuits (EICs) coupled to the top side of the intermediate connection layer; and
an electro-optical interposer coupled to the bottom side of the intermediate connection layer, the electro-optical interposer comprising a plurality of tiles, wherein each tile comprises an electrical layer and an optical layer,
wherein:
the intermediate layer electrically connects a first EIC of the plurality of EICs to a second EIC of the plurality of EICs, wherein the first EIC is adjacent to the second EIC; and
the electro-optical interposer optically connects the first EIC to a third EIC of the plurality of EICs, wherein the third EIC is not adjacent to the first EIC.

2. The multi-reticle device of claim 1, wherein the intermediate connection layer comprises a silicon bridge embedded in a mold matrix, wherein the silicon bridge electrically connects the first EIC to the second EIC.

3. The multi-reticle device of claim 2, wherein the intermediate connection layer further comprises a plurality of vertical connections embedded in the mold matrix, the plurality of vertical connections electrically connecting the first EIC to the electro-optical interposer.

4. The multi-reticle device of claim 1, wherein the intermediate connection layer comprises a silicon interposer.

5. The multi-reticle device of claim 1, wherein the intermediate connection layer comprises a redistribution layer.

6. The multi-reticle device of claim 1, further comprising a redistribution layer coupled to the electro-optical interposer such that the electro-optical interposer is between the intermediate connection layer and the redistribution layer.

7. The multi-reticle device of claim 1, wherein the plurality of EICs comprise a plurality of memory chips and at least one application specific integrated circuit (ASIC).

8. The multi-reticle device of claim 1, wherein the plurality of EICs are arranged in a plurality of unit cells, each unit cell comprising at least one ASIC and at least four memory chips.

9. A multi-reticle device comprising:
a plurality of electrical integrated circuits (EICs) arranged in a plurality of unit cells, each unit cell comprising at least one application specific integrated circuit (ASIC) and a plurality of memory chips;
an intermediate connection layer comprising a top side and a bottom side, wherein the plurality of EICs are coupled to the top side of the intermediate connection layer, wherein the intermediate connection layer is configured to electrically connect an ASIC of a first unit cell of the plurality of units cells to the plurality of memory chips of the first unit cell; and
an electro-optical interposer comprising a plurality of tiles, wherein the electro-optical interposer is coupled to the bottom side of the intermediate connection layer, wherein the electro-optical interposer is configured to optically connect the ASIC of the first unit cell to the plurality of memory chips of a second unit cell of the plurality of unit cells.

10. The multi-reticle device of claim 9, further comprising a plurality of vertical connections formed in the intermediate connection layer, the plurality of vertical connections electrically connecting tiles of the electro-optical interposer to unit cells in accordance with a 1-to-1 correspondence.

11. The multi-reticle device of claim 9, further comprising a plurality of vertical connections formed in the intermediate connection layer, the plurality of vertical connections electrically connecting tiles of the electro-optical interposer to unit cells in accordance with a N-to-1correspondence, where N is greater than 1.

12. The multi-reticle device of claim 9, wherein the intermediate connection layer comprises at least one selected from the group consisting of a redistribution layer, a silicon interposer and a plurality of silicon bridges.

13. The multi-reticle device of claim 9, further comprising a Universal Chiplet Interconnect Express (UCIe) interface configured to place the ASIC of the first unit cell in communication with the plurality of memory chips of the first unit cells.

14. The multi-reticle device of claim 9, further comprising a redistribution layer coupled to the electro-optical interposer such that the electro-optical interposer is between the intermediate connection layer and the redistribution layer.

15. A multi-reticle device comprising:
an intermediate connection layer comprising a top side configured to be electrically coupled to a plurality of electrical integrated circuits (EIC), wherein the intermediate connection layer is configured to electrically connect EICs of the plurality of EICs that are within a cutoff range of one another; and
an electro-optical interposer co-packaged with the intermediate connection layer, wherein the electro-optical interposer is configured to optically connect EICs of the plurality of EICs that are outside the cutoff range of one another.

16. The multi-reticle device of claim 15, wherein the cutoff range is 5 mm.

17. The multi-reticle device of claim 15, wherein the cutoff range is 3 mm.

18. The multi-reticle device of claim 15, wherein the intermediate connection layer comprises at least one selected from the group consisting of a redistribution layer, a silicon interposer and a plurality of silicon bridges.

19. The multi-reticle device of claim 15, further comprising a Universal Chiplet Interconnect Express (UCIe) interface configured to place EICs that are within the cutoff range of one another in communication with one another.

20. The multi-reticle device of claim 15, further comprising a redistribution layer coupled to the electro-optical interposer such that the electro-optical interposer is between the intermediate connection layer and the redistribution layer.
